(19) United States
(12) Patent Application Publication
(10) Pub. No.: US 2017/0234995 A1
(43) Pub. Date: Aug. 17, 2017

(54) SOLID-STATE IMAGE SENSOR, MANUFACTURING METHOD, AND RADIATION IMAGING DEVICE

(71) Applicant: SONY SEMICONDUCTOR SOLUTIONS CORPORATION, Kanagawa (JP)

(72) Inventors: Takeshi YANAGITA, Tokyo (JP); Atsushi SUZUKI, Kanagawa (JP); Yoshihiro KOMATSU, Kanagawa (JP); Yuiti TAKEDA, Kanagawa (JP); Tetsuya OISHI, Kanagawa (JP); Itaru OSHIYAMA, Kanagawa (JP); Kazunobu OTA, Tokyo (JP); Shinji MIYAZAWA, Kanagawa (JP); Hidetoshi OISHI, Kanagawa (JP)

(21) Appl. No.: 15/503,443

(22) PCT Filed: Aug. 11, 2015
(86) PCT No.: PCT/JP2015/072723

§ 371 Date: Feb. 13, 2017

(30) Foreign Application Priority Data
Aug. 21, 2014 (JP) 2014-168205

(51) Int. Cl. G01T 1/20; H01L 27/146

(52) U.S. Cl. CPC G01T 1/2018; H01L 27/14636; H01L 27/14614; H01L 27/14659; H01L 27/14605; H01L 27/14607; H01L 27/1463

(57) ABSTRACT

The present disclosure relates to a solid-state image sensor capable of suppressing deterioration of the noise characteristics and the dark characteristics when capturing an image of radiation, a manufacturing method, and a radiation imaging device. A scintillator converts radiation to visible light. Pixels each including a photodiode are formed in a semiconductor substrate. The photodiode photoelectrically converts the visible light that has been converted by the scintillator. Only a silicon oxide film or a negative fixed charge film is formed on the substrate in an element isolation area of the pixel. The present disclosure can be applied to, for example, a radiation imaging device that captures an image of an X-ray with which an object is irradiated.

### TECHNICAL FIELD

The present disclosure relates to a solid-state image sensor, a manufacturing method, and a radiation imaging device. The present disclosure particularly relates to a solid-state image sensor that can suppress deterioration of noise characteristics and dark characteristics when capturing an image of radiation, a manufacturing method, and a radiation imaging device.

### BACKGROUND ART

An X-ray CMOS image sensor is known as a radiation imaging device that captures images of radiation. The X-ray CMOS image sensor, for example, guides visible light to a CMOS image sensor with a fiber optical plate (FOP) in which lead-glass fibers that completely block X-rays are bundled, after X-rays have been converted into the visible light with a scintillator (refer to, for example, Patent Document 1).

However, if the FOP is placed at an upper layer of an X-ray CMOS image sensor, sensitivity of the X-ray CMOS image sensor decreases because the amount of light is decreased by the FOP. Also, mixture of color deteriorates because an upper layer film of the X-ray CMOS image sensor thickens.

Accordingly, an X-ray CMOS image sensor in which the FOP is not placed at the upper layer has been designed (refer to, for example, Patent Document 2).

### CITATION LIST

### Patent Document

Patent Document 1: WO 09/139209

Patent Document 2: Japanese Patent Application Laid-Open No. 2012-159483

### SUMMARY OF THE INVENTION

### Problems to be Solved by the Invention

However, if the FOP is not placed, the X-rays leak on the CMOS image sensor. As a result, the threshold potential characteristics of a pixel transistor change, and the noise characteristics such as white spots and the dark characteristics deteriorate.

The present disclosure has been made in view of the above situations, and can suppress deterioration of the noise characteristics and the dark characteristics when capturing an image of radiation.

Solutions to Problems

A solid-state image sensor of a first aspect of the present disclosure includes: a radiation converting unit that converts radiation to visible light; and a substrate on which a pixel is formed, the pixel including a photoelectric conversion unit that photoelectrically converts the visible light that has been converted by the radiation converting unit, wherein only an oxide film or a negative fixed charge film is formed on the substrate in an element isolation area of the pixel.

In the first aspect of the present disclosure, a radiation converting unit that converts radiation to visible light and a substrate on which a pixel is formed, the pixel including a photoelectric conversion unit that photoelectrically converts the visible light that has been converted by the radiation converting unit are included, and only an oxide film or a negative fixed charge film is formed on the substrate in an element isolation area of the pixel.

A manufacturing method of a second aspect of the present disclosure is a manufacturing method for a solid-state image sensor. The solid-state image sensor includes: a radiation converting unit that converts radiation to visible light; and a substrate on which a pixel is formed, the pixel including a photoelectric conversion unit that photoelectrically converts the visible light that has been converted by the radiation converting unit, wherein only an oxide film or a negative fixed charge film is formed on the substrate in an element isolation area of the pixel.

In the second aspect of the present invention, a solid-state image sensor is formed. The solid-state image sensor includes: a radiation converting unit that converts radiation to visible light; and a substrate on which a pixel is formed, the pixel including a photoelectric conversion unit that photoelectrically converts the visible light that has been converted by the radiation converting unit, wherein only an oxide film or a negative fixed charge film is formed on the substrate in an element isolation area of the pixel.

A radiation imaging device of a third aspect of the present disclosure includes: a radiation converting unit that converts radiation to visible light; and a substrate on which a pixel is formed, the pixel including a photoelectric conversion unit that photoelectrically converts the visible light that has been converted by the radiation converting unit, wherein only an oxide film or a negative fixed charge film is formed on the substrate in an element isolation area of the pixel.

In the third aspect of the present disclosure, a radiation converting unit that converts radiation to visible light and a substrate on which a pixel is formed, the pixel including a photoelectric conversion unit that photoelectrically converts the visible light that has been converted by the radiation converting unit are included, and only an oxide film or a negative fixed charge film is formed on the substrate in an element isolation area of the pixel.

### Effects of the Invention

According to the first and third aspects of the present disclosure, an image of radiation can be captured. Also, according to the first and third aspects of the present disclosure, deterioration of noise characteristics and dark characteristics can be suppressed when an image of radiation is captured.

According to the second aspect of the present disclosure, a solid-state image sensor can be manufactured. Also, according to the second aspect of the present disclosure, a solid-state image sensor that can suppress deterioration of the noise characteristics and the dark characteristics when capturing an image of radiation can be manufactured.

Note that the effects described herein are not necessarily limited. The effect may be any effect described in this disclosure.

### BRIEF DESCRIPTION OF DRAWINGS

FIG. 1 is a block diagram illustrating an exemplary configuration of one embodiment of a radiation imaging device to which the present disclosure is applied.

FIG. 2 is a cross-sectional view illustrating an exemplary configuration of an X-ray CMOS image sensor of a photographing unit 15 in FIG. 1.

FIG. 3 is a diagram illustrating an exemplary configuration of a CMOS image sensor 32 in FIG. 2.

FIG. 4 is a view of the CMOS image sensor 32 viewed from a scintillator 31.

FIG. 5 is a view illustrating an exemplary configuration of pixels.

FIG. 6 is a cross-sectional view of line A-A′ in FIG. 5.

FIG. 7 is a cross-sectional view of line B-B′ in FIG. 5.

FIG. 8 is a view illustrating another example of the cross section of line A-A′ in FIG. 5.

FIG. 9 is a view illustrating still another example of the cross section of line A-A′ in FIG. 5.

FIG. 10 is a view illustrating another example of the cross section of line B-B′ in FIG. 5.

FIG. 11 is a view illustrating still another example of the cross section of line B-B′ in FIG. 5.

FIG. 12 is a view describing a manufacturing method for a CMOS image sensor when the cross-sectional view of line A-A′ in FIG. 5 is FIG. 6.

FIG. 13 is a view describing a manufacturing method for the CMOS image sensor when the cross-sectional view of line A-A′ in FIG. 5 is FIG. 8.

FIG. 14 is a view describing a manufacturing method for the CMOS image sensor when the cross-sectional view of line A-A′ in FIG. 5 is FIG. 9.

FIG. 15 is a cross-sectional view of line A-A′ in FIG. 5, illustrating a SiN film and a planarized film.

### MODE FOR CARRYING OUT THE INVENTION

### One embodiment

(Exemplary Configuration of One Embodiment of Radiation Imaging Device)

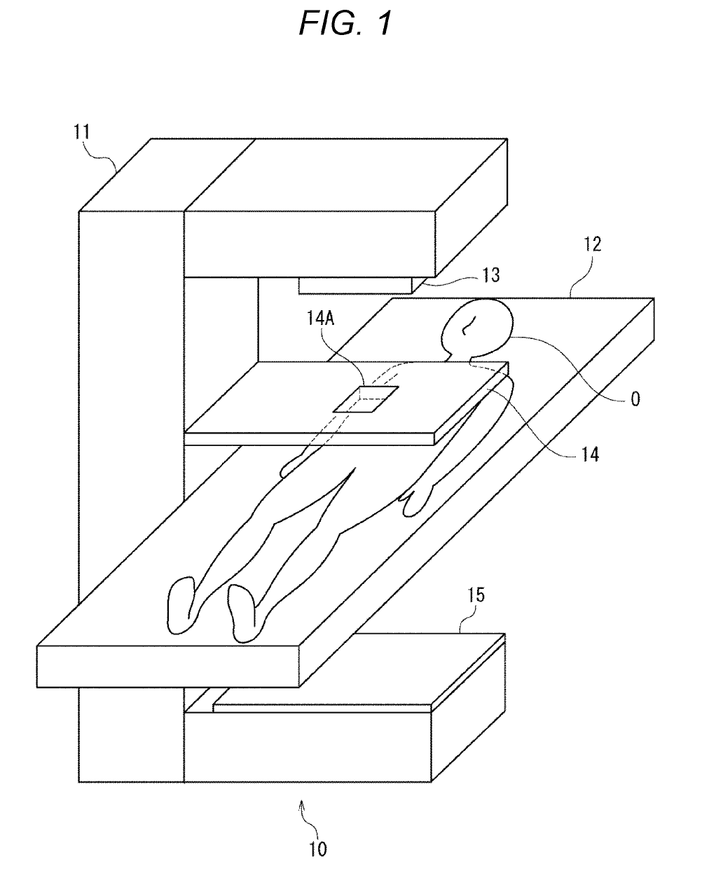

FIG. 1 is a block diagram illustrating an exemplary configuration of one embodiment of the radiation imaging device to which the present disclosure is applied.

The radiation imaging device 10 in FIG. 1 includes an arm 11, a radiographic stand 12, a multi-point parallel X-ray source 13, a shielding plate 14, and an imaging unit 15. The radiation imaging device 10 irradiates an object O (a person in the example in FIG. 1) on the radiographic stand 12 with X-rays, and captures an image.

To be specific, the arm 11 of the radiation imaging device 10 includes a micro processing unit (MPU) not illustrated and various processing circuits inside. The arm 11 controls the multi-point parallel X-ray source 13. Also, the arm 11 holds the radiographic stand 12, the multi-point parallel X-ray source 13, the shielding plate 14, and the imaging unit 15. The radiographic stand 12 is a stand on which the object O is placed.

The multi-point parallel X-ray source 13 includes, for example, a plurality of X-ray guides and a plurality of collimators. The multi-point parallel X-ray source 13 emits parallel beams of X-rays to the radiographic stand 12 under the control of the arm 11.

The shielding plate 14 includes a metal such as lead or iron that can block X-rays, and is placed between the multi-point parallel X-ray source 13 and the radiographic stand 12. The object O is placed between the radiographic stand 12 and the shielding plate 14.

An opening 14A is provided at the shielding plate 14. The X-rays that have been emitted from the multi-point parallel X-ray source 13 irradiate the object O via the opening 14A. Therefore, the object O is placed on the radiographic stand 12, such that the position of the opening 14A corresponds to the position of the object to be radiographed.

The photographing unit 15 includes an X-ray CMOS image sensor, and captures an image by converting X-rays that have been emitted from the multi-point parallel X-ray source 13 via the opening 14A into visible light. The photographing unit 15 holds the resultant image, and transmits the image to another device via a network not illustrated.

(Exemplary Configuration of X-ray CMOS Image Sensor)

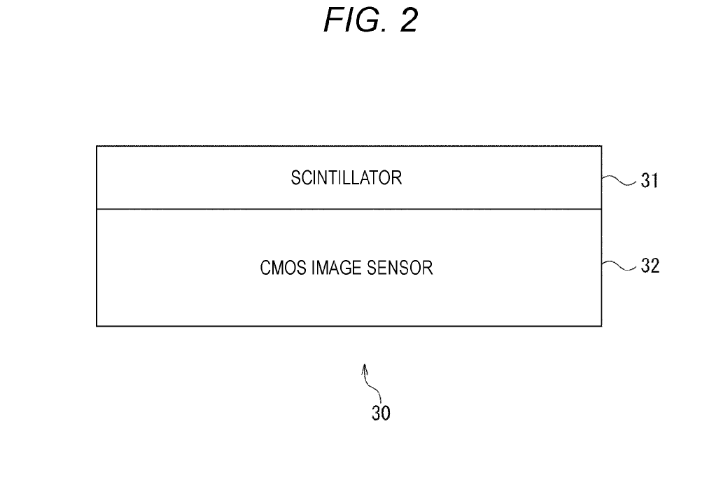

FIG. 2 is a cross-sectional view illustrating an exemplary configuration of an X-ray CMOS image sensor of the photographing unit 15 in FIG. 1.

As illustrated in FIG. 2, the X-ray CMOS image sensor 30 is configured by a scintillator 31 and a CMOS image sensor 32 being arranged in order from the surface irradiated by X-rays.

The scintillator 31 of the X-ray CMOS image sensor 30 functions as a radiation converting unit, and converts X-rays emitted from the multi-point parallel X-ray source 13 via the opening 14A to visible light, and emits the visible light to the CMOS image sensor 32. The CMOS image sensor 32 captures an image of the visible light incident from the scintillator 31, and generates an image.

(Exemplary Configuration of CMOS Image Sensor)

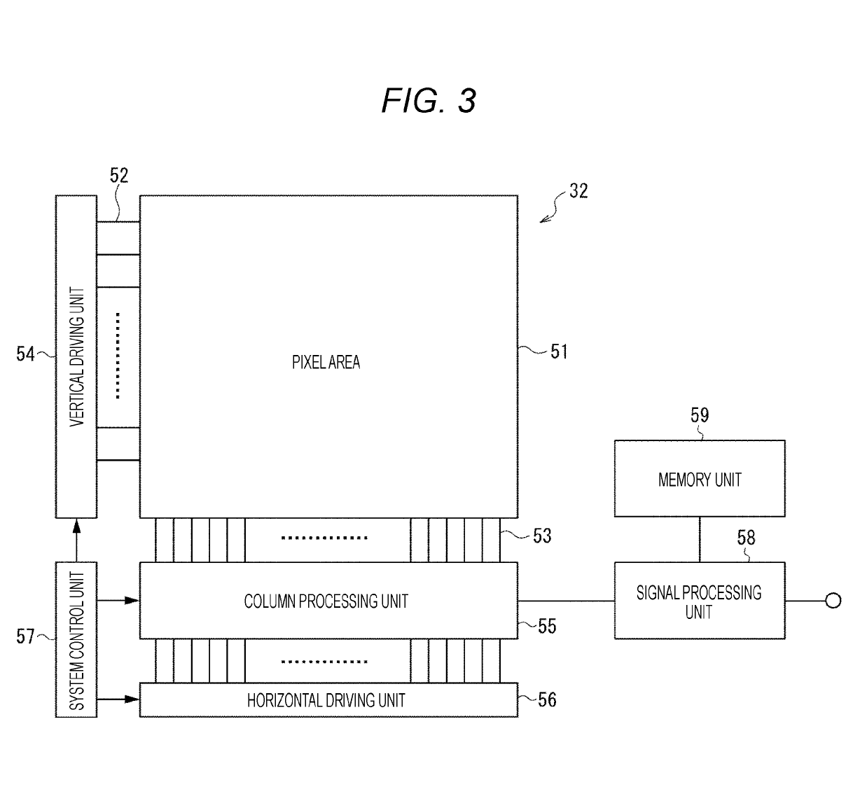

FIG. 3 is a diagram illustrating an exemplary configuration of the CMOS image sensor 32 in FIG. 2.

The CMOS image sensor 32 includes a semiconductor substrate (chip) not illustrated such as a silicon substrate. A pixel area 51, pixel drive lines 52, vertical signal lines 53, a vertical driving unit 54, a column processing unit 55, a horizontal driving unit 56, a system control unit 57, a signal processing unit 58, and a memory unit 59 are formed on the semiconductor substrate.

Pixels are two-dimensionally arranged in a matrix at the pixel area 51 of the CMOS image sensor 32. The pixels include photoelectric conversion elements. The photoelectric conversion elements generate electrical charges corresponding to the amount of incident visible light that has come from the scintillator 31 in FIG. 2, and accumulate the electrical charges inside the photoelectric conversion elements. Thereafter, an image is captured. Also, in the pixel area 51, the pixel drive line 52 is formed for each of the rows and the vertical signal line 53 is formed for each of the columns with respect to the pixels arranged in a matrix.

The vertical driving unit 54, the column processing unit 55, the horizontal driving unit 56, and the system control unit 57 are formed. Reading of pixel signals obtained by an image being captured is controlled at each of the pixels.

To be specific, the vertical driving unit 54 includes a shift register, an address decoder, and the like, and drives each pixel of the pixel area 51, for example, row by row. One terminal of each of the pixel drive lines 52 is connected to an output terminal not illustrated corresponding to each row of the vertical driving unit 54. Illustration of a specific configuration of the vertical driving unit 54 is omitted.

The vertical driving unit 54 includes two scanning systems, i.e., a read scanning system and a sweep scanning system.

The read scanning system selects each row in order so as to sequentially read the pixel signal from each pixel row by row, and outputs a transfer signal, a selection signal, and other signals from the output terminal connected to the pixel drive line 52 of the selected row.

In order to sweep (reset) unwanted charge from the photoelectric conversion element, the sweep scanning system outputs a reset signal from the output terminal connected to the pixel drive line 52 of each row, prior to the scanning of the read system by the time of shutter speed. A so-called electronic shutter operation is performed in order row by row by the scanning by this sweep scanning system. Here, the electronic shutter operation is an operation to discard charge of the photoelectric conversion element and start exposure anew (start accumulation of the charge).

The pixel signals output from each of the pixels of the row selected by the read scanning system of the vertical driving unit 54 are supplied to the column processing unit 55 through each of the vertical signal lines 53.

The column processing unit 55 includes a signal processing circuit for each column of the pixel area 51. Each signal processing circuit of the column processing unit 55 performs noise elimination processing such as correlated double sampling (CDS) processing and signal processing such as A/D conversion processing with respect to the pixel signals output through the vertical signal lines 53 from each of the pixels of the selected row. The column processing unit 55 temporarily holds the processed pixel signal.

The horizontal driving unit 56 includes a shift register, an address decoder, and the like, and sequentially selects the signal processing circuits of the column processing unit 55. The selection scanning by this horizontal driving unit 56 enables the pixel signals, subjected to the signal processing at each signal processing circuit of the column processing unit 55, to be sequentially output to the signal processing unit 58.

The system control unit 57 includes, for example, a timing generator that generates various kinds of timing signals. The system control unit 57 controls the vertical driving unit 54, the column processing unit 55, and the horizontal driving unit 56 on the basis of the various kinds of the timing signals generated by the timing generator.

The signal processing unit 58 includes at least an addition processing function. The signal processing unit 58 performs various signal processing, for example, addition processing with respect to the pixel signal output from the column processing unit 55. Here, the signal processing unit 58 causes the memory unit 59 to store, for example, a result of the signal still in process as needed, and refers to the result at necessary timing. The signal processing unit 58 outputs processed pixel signals.

The memory unit 59 includes, for example, a dynamic random access memory (DRAM) or a static random access memory (SRAM).

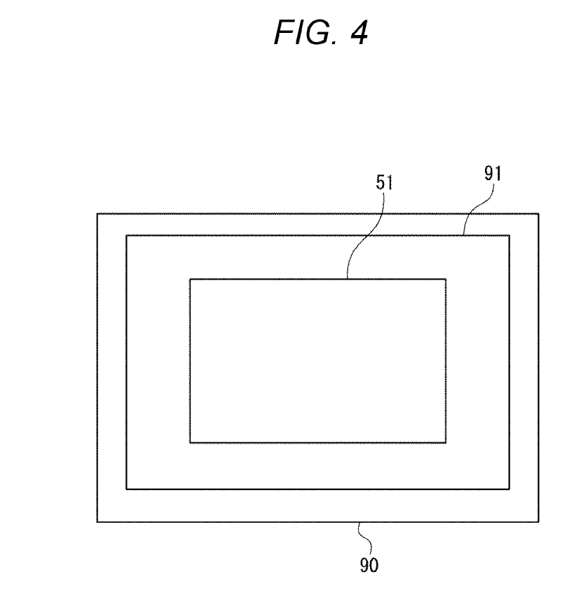

FIG. 4 is a view of the CMOS image sensor 32 viewed from the scintillator 31.

As illustrated in FIG. 4, the pixel area 51 is placed, for example, in the center of a semiconductor substrate 90 of the CMOS image sensor 32. A logic circuit 91 is placed so as to surround the pixel area 51. The logic circuit 91 is, for example, the pixel drive lines 52, the vertical signal lines 53, the vertical driving unit 54, the column processing unit 55, the horizontal driving unit 56, the system control unit 57, the signal processing unit 58, and the memory unit 59.

The X-rays that irradiate the X-ray CMOS image sensor 30 are converted to the visible light by the scintillator 31 and then enter the CMOS image sensor 32. However, some of the X-rays leak and may enter the CMOS image sensor 32 as they are.

Therefore, interconnections made of a metallic element such as copper or tungsten that generates a high-energy fluorescent X-ray are used as interconnections of the pixel area 51. As a result, an adverse effect on the interconnections of the pixel area 51, caused by the X-rays, can be suppressed. In contrast, dark characteristics deteriorate when interconnections made of, for example, Al or AlCu that generates a low-energy (for example, 1 to 2 keV) fluorescent X-ray are used as the interconnections of the pixel area 51.

In addition, the logic circuit 91 on the side of the scintillator 31 is covered with a metal, such as lead that blocks X-rays, because characteristics of transistors included in the logic circuit 91 largely change when X-rays are emitted thereon.

(Exemplary Configuration of Pixels)

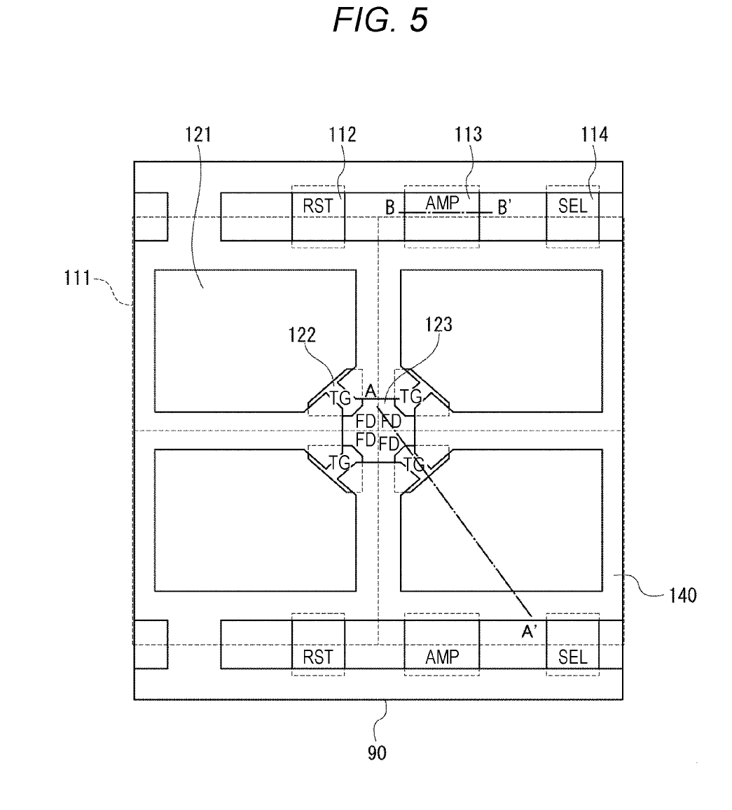

FIG. 5 is a view illustrating an exemplary configuration of the pixels.

FIG. 5 is a view illustrating the semiconductor substrate 90 on which pixels 111 are placed, viewed from the scintillator 31.

In the example of FIG. 5, a reset transistor (RST) 112, an amplification transistor (AMP) 113, and a selection transistor (SEL) 114 are shared among the 2×2 pixels 111. To be specific, each of the pixels 111 includes a photodiode 121, a transfer transistor (TG) 122, and a floating diffusion (FD) 123 provided for each pixel 111, and the reset transistor 112, the selection transistor 114, and the amplification transistor 113 shared among the 2×2 pixels 111.

The photodiode 121 is a photoelectric conversion element in which the incident visible light is photoelectrically converted to charges (here, electrons) corresponding to the amount of light. The transfer transistor 122 transfers, to the floating diffusion 123, the electrons that have been photoelectrically converted at the photodiode 121. The electrons are transferred in response to the transfer signals supplied via the pixel drive lines 52 in FIG. 3.

The reset transistor 112 resets the potential of the floating diffusion 123 in response to the reset signals supplied via the pixel drive lines 52.

The amplification transistor 113 amplifies the potential of the floating diffusion 123, and supplies the selection transistor 114 with voltage corresponding to the potential. The selection transistor 114 supplies the vertical signal lines 53 in FIG. 3 with the voltage amplified by the amplification transistor 113. The voltage is supplied in response to the selection signals supplied via the pixel drive lines 52.

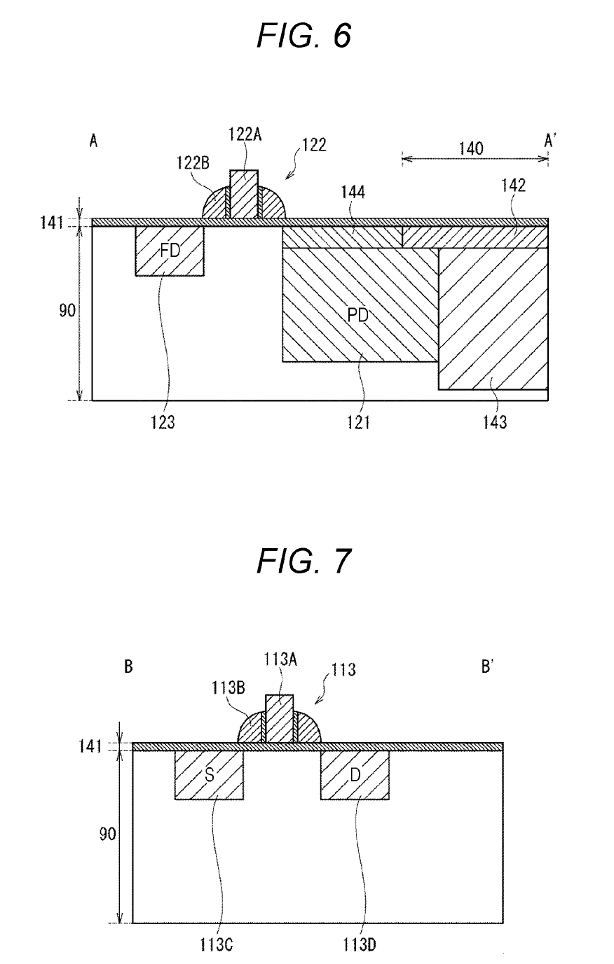

FIG. 6 is a cross-sectional view of line A-A′ in FIG. 5.

As illustrated in FIG. 6, the transfer transistor 122 includes a gate electrode 122A formed on a surface to be irradiated (surface on the side of the scintillator 31) of the semiconductor substrate 90, and a side wall 122B covering the gate electrode 122A.

A FLAT pixel isolation method is used as a method for element isolation of the pixels 111. To be specific, only a silicon oxide film 141, not any oxide element isolation area, is placed on the surface to be irradiated of the semiconductor substrate 90 of an element isolation area 140 placed around the photodiode 121. The details of the FLAT pixel isolation method are described in Japanese Patent Application Laid-Open No. 2007-158031. The thickness of the silicon oxide film 141 is 10 nm or less.

Note that the silicon oxide film 141 is formed not only on the element isolation area 140, but on the whole area of the surface to be irradiated of the semiconductor substrate 90. Here, the thickness of the oxide film is the same at the element isolation area 140 and at an area other than the element isolation area 140. However, the thickness of the oxide film may be different as long as the thickness is 10 nm or less.

As described above, in the CMOS image sensor 32, the method for the element isolation is the FLAT pixel isolation method, and the thickness of the silicon oxide film 141 is 10 nm or less. Therefore, generation of positive fixed charge in the silicon oxide film 141 and generation of an interface state, caused by the irradiation of the X-rays, at the interface between the silicon oxide film 141 and the semiconductor substrate 90 can be suppressed. As a result, for example, reduction in element isolation withstand voltage and deterioration of the noise characteristics and the dark characteristics can be suppressed.

Note that the CMOS image sensor 32 here satisfies both of the conditions, i.e., the method for the element isolation is the FLAT pixel isolation method, and the thickness of the silicon oxide film 141 is 10 nm or less. However, the CMOS image sensor 32 may satisfy only one of the conditions. Even in this case, the CMOS image sensor 32 can suppress, for example, reduction in element isolation withstand voltage and deterioration of the noise characteristics and the dark characteristics.

In addition, a relatively shallow highly concentrated semiconductor area 142 is formed on the side of the surface to be irradiated of the semiconductor substrate 90 of the element isolation area 140. A semiconductor area 143 which is deep enough for the element isolation is formed continuously from the semiconductor area 142.

The photodiode 121 has a hole accumulation diode (HAD) structure. A pinning area 144 having an impurity concentration of 10¹⁹ atoms/cm³ or more is formed on the side of the surface to be irradiated (outside surface) in the semiconductor substrate 90, with respect to the photodiode 121. A dark current can be suppressed by the pinning area 144 having an impurity concentration of 10¹⁹ atoms/cm³ or more.

FIG. 7 is a cross-sectional view of line B-B′ in FIG. 5.

As illustrated in FIG. 7, the amplification transistor 113 includes a gate electrode 113A, a side wall 113B, a source area 113C, and a drain area 113D. The gate electrode 113A and the side wall 113B are placed on the surface to be irradiated of the semiconductor substrate 90. The side wall 113B covers the gate electrode 113A. The source area 113C and the drain area 113D are placed in the semiconductor substrate 90. The silicon oxide film 141 is formed on the semiconductor substrate 90.

Note that the silicon oxide film 141 is formed on the whole area of the surface to be irradiated of the semiconductor substrate 90 in the examples in FIGS. 6 and 7. However, a negative fixed charge film (pinning reinforced film) 161 that includes HfO₂, AL₂O₃ or TaO₂ can replace a part of the silicon oxide film 141.

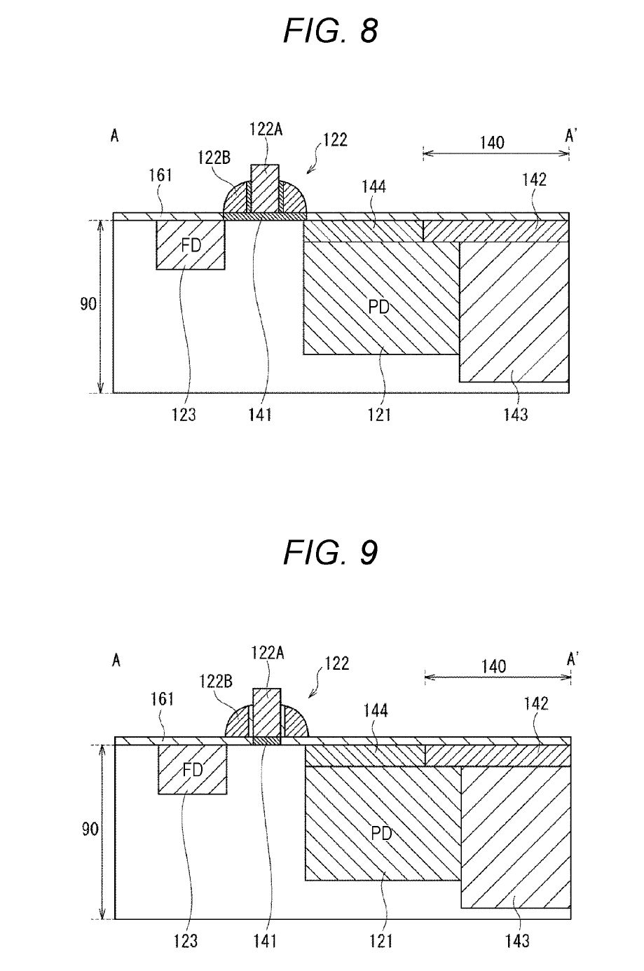

As illustrated in FIG. 8, the negative fixed charge film 161 can replace the silicon oxide film 141 on the semiconductor substrate 90, for example, the area including the element classification area 140, other than a part below the side wall 122B and the gate electrode 122A of the transfer transistor 122.

As illustrated in FIG. 9, the negative fixed charge film 161 can replace the silicon oxide film 141 on the semiconductor substrate 90, likewise, the area including the element classification area 140, other than the part below the gate electrode 122A.

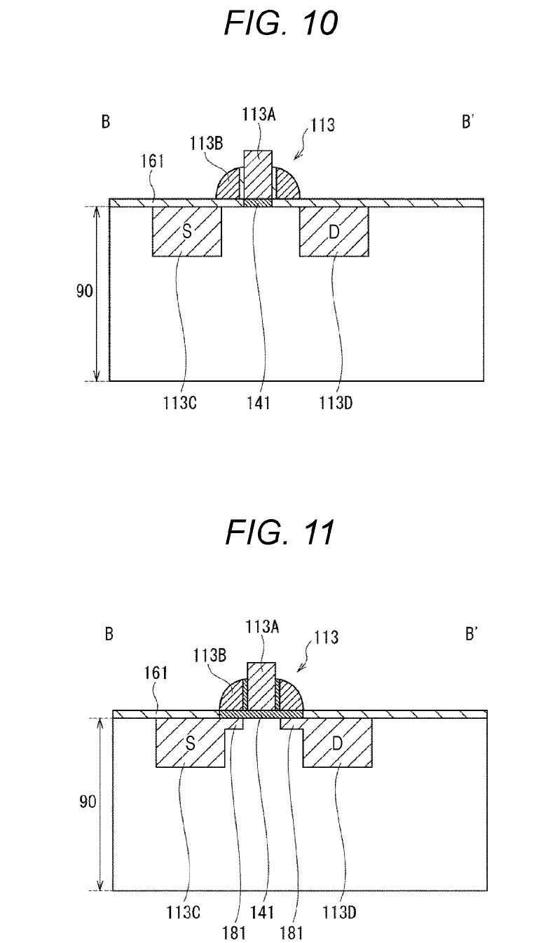

As illustrated in FIG. 10, the negative fixed charge film 161 can replace the silicon oxide film 141 on the semiconductor substrate 90, for example, the area including the element classification area 140, other than a part below the gate electrode 113A of the amplification transistor 113. Although the illustration is omitted, the negative fixed charge film 161 can replace the silicon oxide film 141 on the semiconductor substrate 90, likewise, the area including the element classification area 140, other than the part below the gate electrode 113A and the side wall 113B.

As mentioned above, the negative fixed charge generated in the negative fixed charge film 161 by irradiation of the X-rays can be increased when the negative fixed charge film 161 is formed on the semiconductor substrate 90. As a result, the pinning is enhanced and the dark current can be suppressed.

Note that, although the illustrations are omitted, the reset transistor 112 and the selection transistor 114 are configured similarly to the amplification transistor 113.

Whether to form the silicon oxide film 141 or the negative fixed charge film 161 at the part below the side wall of each of the transistors is determined, for example, according to the demanded characteristic of the transistor.

As illustrated in FIG. 9, the negative fixed charge film 161 is formed at the part below the side wall 122B, for example, when the pinning of the transfer transistor 122 is expected to be enhanced.

In addition, when LDDs 181 are formed in the semiconductor substrate 90 at the part below the side wall 113B as illustrated in FIG. 11, the noise reduces compared with when the LDDs 181 are not formed. Therefore, the silicon oxide film 141 is formed, for example, at the part below the side wall 113B.

(Description of Manufacturing Method for CMOS Image Sensor)

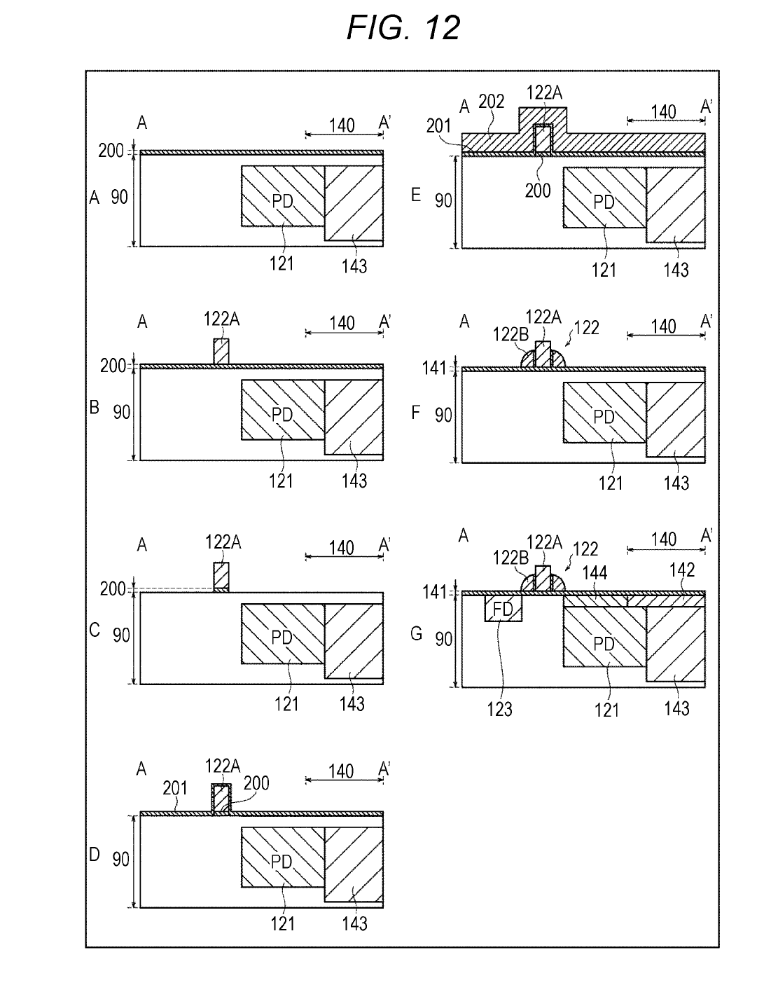

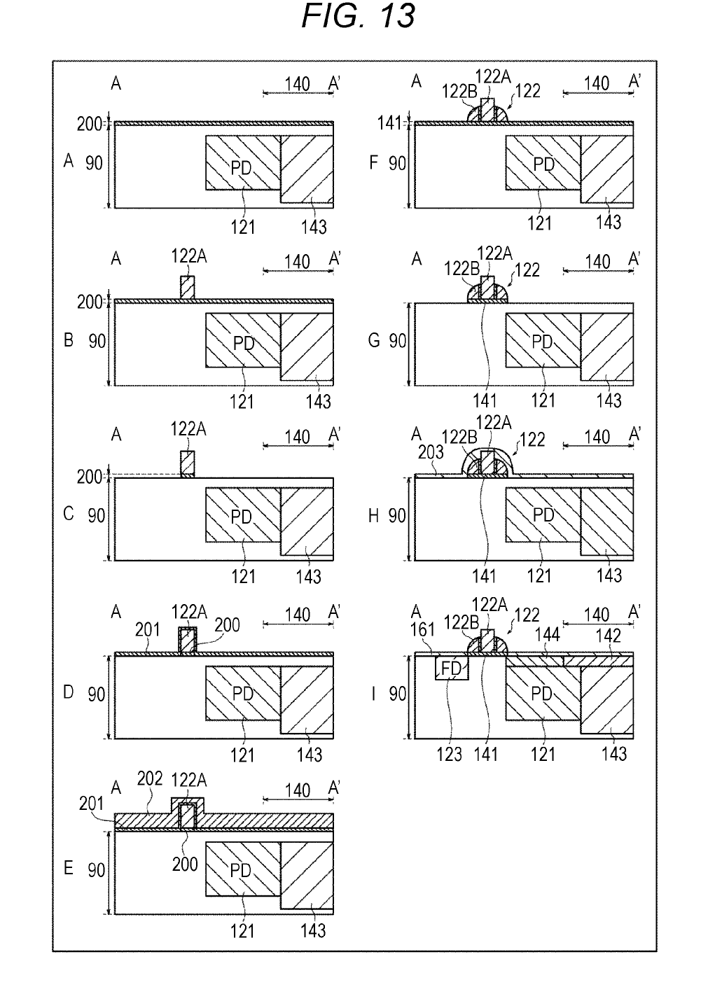

FIG. 12 is a view describing the manufacturing method for the area near the transfer transistor 122 of the CMOS image sensor 32 when the cross-sectional view of line A-A′ in FIG. 5 is FIG. 6.

As illustrated in A in FIG. 12, first, the photodiode 121, the semiconductor area 143 and the like are formed in the semiconductor substrate 90, and a silicon oxide film 200 is formed on the semiconductor substrate 90.

Next, as illustrated in B in FIG. 12, the gate electrode 122A is formed on the silicon oxide film 200. Thereafter, as illustrated in C in FIG. 12, the silicon oxide film 200 on the semiconductor substrate 90 is removed. As a result, the silicon oxide film 200 at the part below the gate electrode 122A is formed as a part of the silicon oxide film 141.

Next, as illustrated in D in FIG. 12, a new silicon oxide film 201 is formed on the semiconductor substrate 90 on which the gate electrode 122A has been formed. Thereafter, as illustrated in E in FIG. 12, a SiN film 202 is formed on the silicon oxide film 201.

Next, as illustrated in F in FIG. 12, the SiN film 202 on an area other than the area of the transfer transistor 122 is removed, and the silicon oxide film 201 and the SiN film 202 at a part above the gate electrode 122A are removed. As a result, the silicon oxide film 141 and the side wall 122B are formed.

Thereafter, as illustrated in G in FIG. 12, for example, the floating diffusion 123, the semiconductor area 142, and the pinning area 144 are formed in the semiconductor substrate 90. The area near the transfer transistor 122 of the CMOS image sensor 32 is manufactured as described above.

A planarized film is formed on a surface of the CMOS image sensor 32 after manufacturing of the CMOS image sensor 32. The surface is where the transfer transistor 122 and the like are placed. The CMOS image sensor 32 is connected to the scintillator 31 via the planarized film.

FIG. 13 is a view describing the manufacturing method for the area near the transfer transistor 122 of the CMOS image sensor 32 when the cross-sectional view of line A-A′ in FIG. 5 is FIG. 8.

A to F in FIG. 13 are similar to A to F in FIG. 12, and therefore the descriptions thereof are omitted. As illustrated in F in FIG. 13, the SiN film 202 on an area other than the area of the transfer transistor 122, and the silicon oxide film 200 and the SiN film 202 at the part above the gate electrode 122A are removed. Thereafter, as illustrated in G in FIG. 13, the silicon oxide film 201 on the semiconductor substrate 90 is removed. As a result, the silicon oxide film 141 is formed.

Thereafter, as illustrated in H in FIG. 13, a negative fixed charge film 203 is formed on the semiconductor substrate 90. Next, as illustrated in I in FIG. 13, the negative fixed charge film 161 is formed by the negative fixed charge film 203 at the area of the transfer transistor 122 being removed. In addition, for example, the floating diffusion 123, the semiconductor area 142, and the pinning area 144 are formed in the semiconductor substrate 90. The area near the transfer transistor 122 of the CMOS image sensor 32 is manufactured as described above.

The planarized film is formed on a surface of the CMOS image sensor 32 after manufacturing of the CMOS image sensor 32. The surface is where the transfer transistor 122 and the like are placed. The CMOS image sensor 32 is connected to the scintillator 31 via the planarized film.

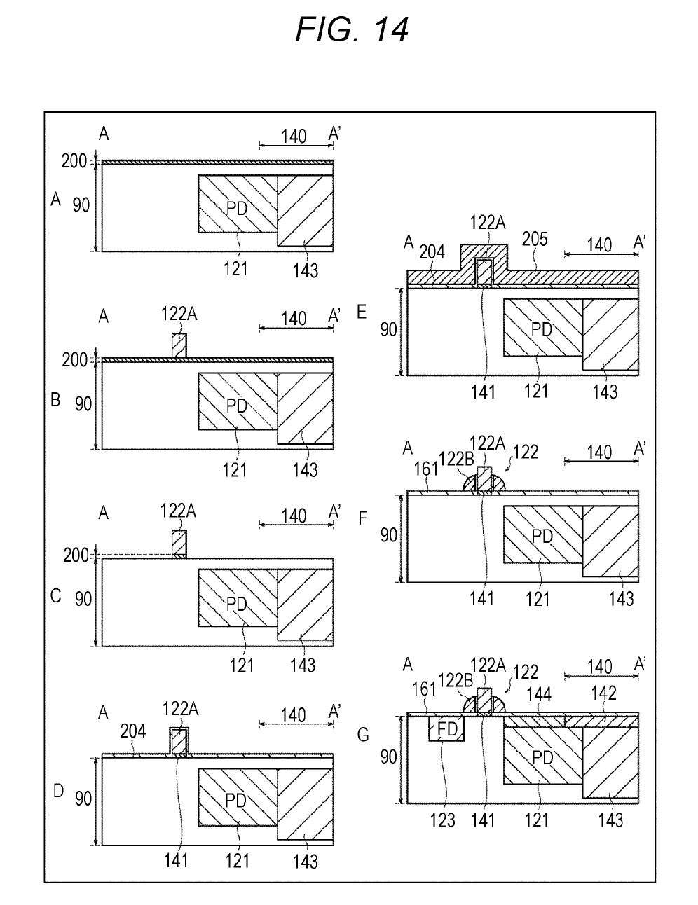

FIG. 14 is a view describing the manufacturing method for the area near the transfer transistor 122 of the CMOS image sensor 32 when the cross-sectional view of line A-A′ in FIG. 5 is FIG. 9.

A to C in FIG. 14 are similar to A to C in FIG. 12, and therefore the descriptions thereof are omitted. As illustrated in D in FIG. 14, a negative fixed charge film 204 is formed on the semiconductor substrate 90, after the silicon oxide film 141 is formed at the part below the gate electrode 122A in C in FIG. 14.

Thereafter, as illustrated in E in FIG. 14, a SiN film 205 is formed on the negative fixed charge film 204. Next, as illustrated in F in FIG. 14, the SiN film 205 on an area other than the area of the transfer transistor 122 is removed, and the negative fixed charge film 204 and the SiN film 205 at the part above the gate electrode 122A are removed. As a result, the negative fixed charge film 161 and the side wall 122B are formed.

Thereafter, as illustrated in G in FIG. 14, for example, the floating diffusion 123, the semiconductor area 142, and the pinning area 144 are formed in the semiconductor substrate 90. The area near the transfer transistor 122 of the CMOS image sensor 32 is manufactured as described above.

A planarized film is formed on a surface of the CMOS image sensor 32 after manufacturing of the CMOS image sensor 32. The surface is where the transfer transistor 122 and the like are placed. The CMOS image sensor 32 is connected to the scintillator 31 via the planarized film.

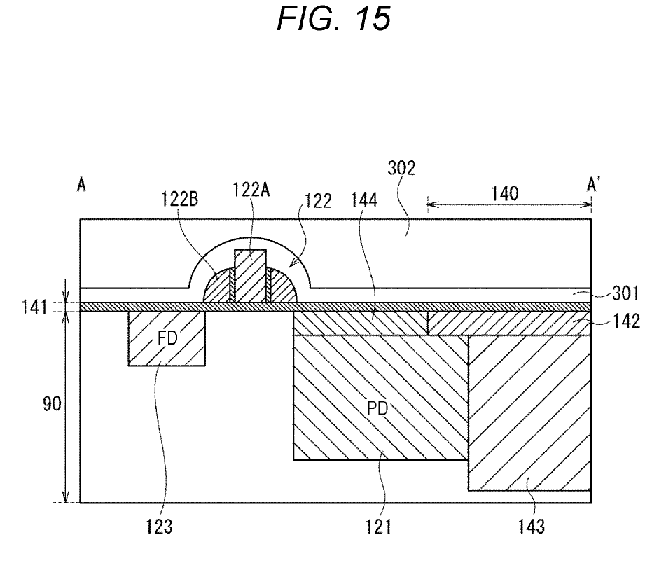

Note that although the illustrations are omitted in the above descriptions, in fact, the SiN film is formed on the silicon oxide film 141 so as to cover the upper parts of the gate electrodes of the reset transistor 112, the amplification transistor 113, the selection transistor 114, and the transfer transistor 122. The thickness of the SiN film is 20 nm or more and 200 nm or less. A SiO2 film is formed as the planarized film on this SiN film. FIG. 15 is a cross-sectional view of line A-A′ in FIG. 5 illustrating a SiN film 301 and a planarized film 302 covering the gate electrode 122A of the transfer transistor 122.

The effects described herein are just examples, and are not limited to these examples and may include different effects.

Note that the present disclosed embodiment is not limited to the embodiment mentioned above, and various modifications can be applied thereto as long as they do not depart from the gist of the present disclosure.

The present disclosure can be applied to, for example, a radiation imaging device that captures an image of radiation other than an X-ray.

Note that LDDs may be formed similarly to the amplification transistor 113, on the semiconductor substrate 90 at the part below the side wall 122B of the transfer transistor 122.

Note that the present disclosure can also be configured as follows.

(1)

A solid-state image sensor including:
a radiation converting unit that converts radiation to visible light; and
a substrate on which a pixel is formed, the pixel including a photoelectric conversion unit that photoelectrically converts the visible light that has been converted by the radiation converting unit, wherein
only an oxide film or a negative fixed charge film is formed on the substrate in an element isolation area of the pixel.

(2)

The solid-state image sensor according to (1), wherein the oxide film has a thickness of 10 nanometers or less.

(3)

The solid-state image sensor according (2), wherein the oxide film is formed on the whole area of the substrate.

(4)

The solid-state image sensor according to any of (1) to (3), wherein an impurity concentration of a surface corresponding to the photoelectric conversion unit in the substrate is 10¹⁹ atoms/cm³ or more.

(5)

The solid-state image sensor according to any of (1) to (4), wherein an interconnection of the pixel is formed of copper or tungsten.

(6)

The solid-state image sensor according to any of (1) to (5), wherein
a gate electrode of a transistor of the pixel and a side wall covering the gate electrode are formed on the substrate,
the oxide film is formed on the substrate at a part below the side wall and the gate electrode, and the negative fixed charge film is formed on the substrate at an area other than the part below the gate electrode and the side wall.

(7)

The solid-state image sensor according to any of (1) to (5), wherein
a gate electrode of a transistor of the pixel and a side wall covering the gate electrode are formed on the substrate,
the oxide film is formed on the substrate at a part below the gate electrode, and
the negative fixed charge film is formed on the substrate at an area other than the part below the gate electrode.

(8)

The solid-state image sensor according to any of (1) to (7), wherein the negative fixed charge film is HfO₂, AL₂O₃ or TaO₂.

(9)

The solid-state image sensor according to any of (1) to (8), further including:
a SiN film covering an upper part of a gate electrode of a transistor of the pixel, wherein
the SiN film has a thickness of 20 nanometers or more and 200 nanometers or less.

(10)

A manufacturing method for a solid-state image sensor including:
a radiation converting unit that converts radiation to visible light; and
a substrate on which a pixel is formed, the pixel including a photoelectric conversion unit that photoelectrically converts the visible light that has been converted by the radiation converting unit, wherein
only an oxide film or a negative fixed charge film is formed on the substrate in an element isolation area of the pixel.

(11)

A radiation imaging device including:
a radiation converting unit that converts radiation to visible light; and
a substrate on which a pixel is formed, the pixel including a photoelectric conversion unit that photoelectrically converts the visible light that has been converted by the radiation converting unit, wherein
only an oxide film or a negative fixed charge film is formed on the substrate in an element isolation area of the pixel.

### REFERENCE SIGNS LIST

10 Radiation imaging device

31 Scintillator

90 Semiconductor substrate

111 Pixel

121 Photodiode

122 Transfer transistor

122A Gate electrode

122B Side wall

140 Element isolation area

141 Silicon oxide film

161 Negative fixed charge film

301 SiN film

1. A solid-state image sensor comprising:
a radiation converting unit that converts radiation to visible light; and
a substrate on which a pixel is formed, the pixel including a photoelectric conversion unit that photoelectrically converts the visible light that has been converted by the radiation converting unit, wherein
only an oxide film or a negative fixed charge film is formed on the substrate in an element isolation area of the pixel.

2. The solid-state image sensor according to claim 1, wherein the oxide film has a thickness of 10 nanometers or less.

3. The solid-state image sensor according to claim 2, wherein the oxide film is formed on the whole area of the substrate.

4. The solid-state image sensor according to claim 1, wherein an impurity concentration of a surface corresponding to the photoelectric conversion unit in the substrate is 10¹⁹ atoms/cm³ or more.

5. The solid-state image sensor according to claim 1, wherein an interconnection of the pixel is formed of copper or tungsten.

6. The solid-state image sensor according to claim 1, wherein
a gate electrode of a transistor of the pixel and a side wall covering the gate electrode are formed on the substrate,
the oxide film is formed on the substrate at a part below the side wall and the gate electrode, and
the negative fixed charge film is formed on the substrate at an area other than the part below the gate electrode and the side wall.

7. The solid-state image sensor according to claim 1, wherein
a gate electrode of a transistor of the pixel and a side wall covering the gate electrode are formed on the substrate,
the oxide film is formed on the substrate at a part below the gate electrode, and
the negative fixed charge film is formed on the substrate at an area other than the part below the gate electrode.

8. The solid-state image sensor according to claim 1, wherein the negative fixed charge film is HfO₂, AL₂O₃ or TaO₂.

9. The solid-state image sensor according to claim 1, further comprising:
a SiN film covering an upper part of a gate electrode of a transistor of the pixel, wherein
the SiN film has a thickness of 20 nanometers or more and 200 nanometers or less.

10. A manufacturing method for a solid-state image sensor comprising:
a radiation converting unit that converts radiation to visible light; and
a substrate on which a pixel is formed, the pixel including a photoelectric conversion unit that photoelectrically converts the visible light that has been converted by the radiation converting unit, wherein
only an oxide film or a negative fixed charge film is formed on the substrate in an element isolation area of the pixel.

11. A radiation imaging device comprising:
a radiation converting unit that converts radiation to visible light; and
a substrate on which a pixel is formed, the pixel including a photoelectric conversion unit that photoelectrically converts the visible light that has been converted by the radiation converting unit, wherein
only an oxide film or a negative fixed charge film is formed on the substrate in an element isolation area of the pixel.
